(19) United States
(12) Patent Application Publication
(10) Pub. No.: US 2008/0068107 A1
(43) Pub. Date: Mar. 20, 2008

(54) High performance, flexible programmable clock circuit

(76) Inventor: Thomas M. Luich, Puyallup, WA (US)

Correspondence Address: MICHAEL J. URE, 10518 PHIL PLACE, CUPERTINO, CA, 95014, US

(21) Appl. No.: 11/516,934

(22) Filed: Sep. 6, 2006

(51) Int. Cl. H03B 5/32

(52) U.S. Cl. 331/158

(57) ABSTRACT

A Programmable Crystal Oscillator/Programmable Voltage Controlled Crystal Oscillator (PXO/PVCXO) is formed on a single die that will accept multiple crystals and maintain optimum performance. A programmable transconductance amplifier allows configuration of the transconductance by configuration information stored in non-volatile memory, to match the requirements of the crystal series resistance, frequency, and load of the tank. Programmable varactors are provided in such a manner as to achieve pulling range independent of frequency select address, allowing VCXO operation. Steps are taken to effectively remove the parasitic capacitance of the long metal line leading to a phase detector, by tuning its parasitic capacitance with the tank of the crystal oscillator, and placing a low gain buffer at the phase detector.

### BACKGROUND OF THE INVENTION

1. Field of the Invention

The present invention relates to programmable clock circuits including Programmable. Crystal Oscillators (PXOs) and variants thereof. Once such variant is a Programmable Voltage Controlled Crystal Oscillator (hereinafter PVCXO).

2. State of the Art

U.S. Pat. Nos. 5,952,890, 6,188,290 and 6,665,860 describe a PXO where a quartz crystal is used in conjunction with an integrated Phase Locked Loop (PLL) and Non Volatile Memory (NVM) to accomplish a frequency synthesizer that can generate a variety of frequencies. Fine frequency steps are achieved by programmably “pulling” the crystal in. This pulling allows the reference frequency of the PLL to be operated at a higher frequency, thereby reducing the amount of multiplication (and consequently phase noise) required.

FIG. 1 shows a typical crystal oscillator configuration (XOC). A crystal XO is connected in parallel with a bias resistance Rb and an amplifier A. A tank circuit is formed by connecting respective load capacitors Cl to the opposite crystal electrodes, one plate of each of the capacitors being grounded.

Table 1 shows typical process variation for the parameter Rs for typical, AT cut quartz crystals that would fit into the package size listed. These crystals are typical quartz crystals used in a PXO.

TABLE 1

| | | | Rs min - | Rs max - | C1 - | |
|---|---|---|---|---|---|---|
| Package | | Freq(MHz) | Ohms | Ohms | fF | Co - pF |
| 5 × 7 | mm | 20 | 5 | 25 | 6.44 | 2.16 |
| | | 25 | 5 | 20 | 15.21 | 4.89 |
| | | 32 | 5 | 20 | 17.11 | 4.66 |
| | | 40 | 5 | 25 | 11.22 | 3.38 |
| 5 × 3.2 | mm | 20 | 5 | 25 | 7.89 | 2.19 |
| | | 25 | 5 | 25 | 10.14 | 2.66 |
| | | 32 | 5 | 20 | 12.11 | 3.2 |
| | | 40 | 5 | 20 | 14.1 | 3.7 |
| 3.2 × 2.5 | mm | 20 | 20 | 60 | 21.29 | 1.05 |
| | | 25 | 20 | 60 | 11.07 | 1.19 |
| | | 32 | 15 | 50 | 7.19 | 1.06 |
| | | 40 | 10 | 45 | 4.28 | 1.2 |

As can be seen from Table 1, the critical parameter Rs, can vary by up to 5× for a single type of crystal, with total variation (for these typical examples), of 12×. This implies that the minimum transconductance, Gm, of the amplifier used to overcome resistive losses in the tank must be designed for the worst case of all values listed.

For a PXO, the crystal is used as the fine frequency adjustment. In the foregoing patents, a programmable load is provided, with the value of the loads on the tank being programmable over the entire range of the programmable load. This variable load further increases the requirements on Gm of the amplifier, in accordance with the following first order relationship for oscillator startup:

Gm>RS/X_{c}² (1)

where X_{c} is load capacitors impedance, assuming the loads on both sides of the crystal are equal.

FIG. 2 shows the required Gm for the crystals listed in Table 1, with a load variation (programmable) of 6 pF to 14 pF.

Note that the various parametric changes force Gm to vary by almost two orders of magnitude, which is a severe requirement on the amplifier, even using automatic amplitude control. For this reason, the prior art PXO uses a single frequency crystal, with limited variation of Rs.

As seen in FIG. 2, even selecting a single crystal, the required Gm varies, from minimum to maximum conditions, by up to an order of magnitude, depending on the crystal. In the prior art design, the worst case conditions are used to set the Gm of the amplifier, guaranteeing startup under all circumstances. For minimum programming and Rs conditions, the amplifier will have excess gain, which increases circuit power, harmonic distortion and clipping of the sinusoidal output, risks possible damage to crystal, and introduces spurious tones (especially in small footprint crystals).

Voltage controlled crystal oscillators (VCXOs) are crystal oscillators that provide the ability to modulate the crystal frequency (usually by 1-200 PPM) from an analog pin. A typical ideal curve plotting VCXO pulling characteristic versus control pin voltage is shown in FIG. 3.

The usual implementation of this function is achieved by adding a varactor to the crystal oscillator tank and connecting the control voltage for the varactor to a separate pin for end users to access. The magnitude of the pulling is determined by the crystal parameters, the fixed and parasitic capacitance connected to the tank, and the minimum and maximum capacitance values (cmin/cmax) of the varactor.

FIG. 4 shows the pulling characteristics of the crystals in Table 1 as a function of capacitance. In each case, the load capacitance is for each side of the crystal, as depicted in FIG. 1.

The pulling characteristic of FIG. 4 can be achieved in conventional fashion as depicted in FIG. 5. As shown therein, a first series of binary weighted capacitors Csbin1 is formed with one plate of each capacitor being connected to one side of the crystal oscillator configuration. The other plate of the capacitors is connected through a controllable transistor switch (T1₁, T2₁, etc.) to ground. A second, complementary, series of binary weighted capacitors Csbin2 is connected to the other side of the crystal oscillator configuration. Capacitors of the same weight on opposite sides of the crystal oscillator configuration are paired together, and their respective transistor switches are commonly controlled. Hence, a 1X_SELECT input signal, when asserted, couples capacitors of weight 1 into the circuit on each side of the crystal oscillator configuration such that the frequency of oscillation is reduced. A 2X_SELECT input signal, when asserted, couples capacitors of weight 2 into the circuit on each side of the crystal oscillator configuration such that the frequency of oscillation is further reduced, etc. An output circuit OUT includes a buffer amplifier B connected via a metal interconnect line to an input terminal of a phase detector (not shown). As previously described, the length of the metal interconnect line may be hundreds of microns such that the line has significant associated capacitance. This capacitance is represented by the capacitor Cline.

Binary weighted load capacitors are digitally selected by on die NVM, such that increasing the digital address value increases the load on the XO. FIG. 6 depicts the same characteristic as FIG. 4, only as a function of 128 addresses that would be present in a seven bit implementation of FIG. 5.

By adding a varactor to both sides of the tank in FIG. 5, the PXO can serve as a PVCXO. FIG. 7 shows the pulling capability for varactor with 1-3 pF capacitance range, with fixed load capacitance range of 3-13 pF for a 20 MHz, 5 mm×7 mm crystal. The fixed load capacitance is divided into 128 addresses and serves as the fine frequency select for the PXO function.

The curve shows that as the address increases (more capacitance is added to the crystal tank, reducing the frequency), the pulling due to the varactor is reduced. Therefore, the voltage controlled pulling due to the varactor, which is controlled by the end user, is a function of the fine frequency programming, and can vary by over 7×. This characteristic is worsened by adding a range of different crystals, such as the range of crystals described in Table 1. The PXO of the referenced patents does not use voltage control for this reason.

Typically, the crystal oscillator is located between the pads that connect to both sides of the crystal. The sinusoidal signal is then amplified to a square wave in order to drive a digital phase detector. The phase detector is typically located within a PLL, which in a typical integrated circuit implementation can be hundreds of microns away from the XO. The buffer, which is used to square up the sinusoid, also acts a buffer to drive the parasitic capacitance of the interconnect, and can be composed of several inverters, depending on the length of the metal line. The act of driving this capacitance causes power supply noise at the crystal frequency which feeds through to the outputs as spurious peaks in the spectrum, and causes an increase in jitter.

### SUMMARY OF THE INVENTION

The present invention, generally speaking, provides for a Programmable Crystal Oscillator/Programmable Voltage Controlled Crystal Oscillator on a single die that will accept multiple crystals and maintain optimum performance. A programmable transconductance amplifier allows configuration of the transconductance by configuration information stored in non-volatile memory, to match the requirements of the crystal series resistance, frequency, and load of the tank. Programmable varactors are provided in such a manner as to achieve pulling range independent of frequency select address, allowing VCXO operation. Steps are taken to effectively remove the parasitic capacitance of the long metal line leading to a phase detector, by tuning its parasitic capacitance with the tank of the crystal oscillator, and placing a low gain buffer at the phase detector.

### BRIEF DESCRIPTION OF THE DRAWING

The present invention may be more fully understood from the following description in conjunction with the appended drawing. In the drawing:

FIG. 1 is a circuit diagram of a typical crystal oscillator configuration.

FIG. 2 is a graph illustrating amplifier transconductance (Gm) requirements as a function of frequency for different crystal blanks.

FIG. 3 is a graph illustrating an ideal crystal oscillator pulling curve as a function of pin voltage.

FIG. 4 is a graph illustrating crystal oscillator pulling as a function of load capacitance for different crystal blanks.

FIG. 5 is a circuit diagram of a prior art PXO configuration.

FIG. 6 is a graph illustrating, crystal oscillator pulling as a function of address number (programming word) for different crystal blanks, for a circuit similar to that of FIG. 5 but modified in accordance with one embodiment of the present invention.

FIG. 7 is a graph illustrating pull range as a function of address number for a VCXO in accordance with one embodiment of the present invention.

FIG. 8 is a block diagram of a programmable voltage controlled crystal oscillator in accordance with one embodiment of the present invention.

FIG. 9 is a circuit diagram of the VCXO pulling stage of FIG. 8.

FIG. 10 is a circuit diagram of the VCO transconductance stage of FIG. 8.

FIG. 11 is a schematic diagram illustrating a tunnel cross section of a tunnel interconnect connecting the crystal output signal to the output buffer stage of FIG. 8.

FIG. 12 is a circuit diagram of the output buffer stage of FIG. 8.

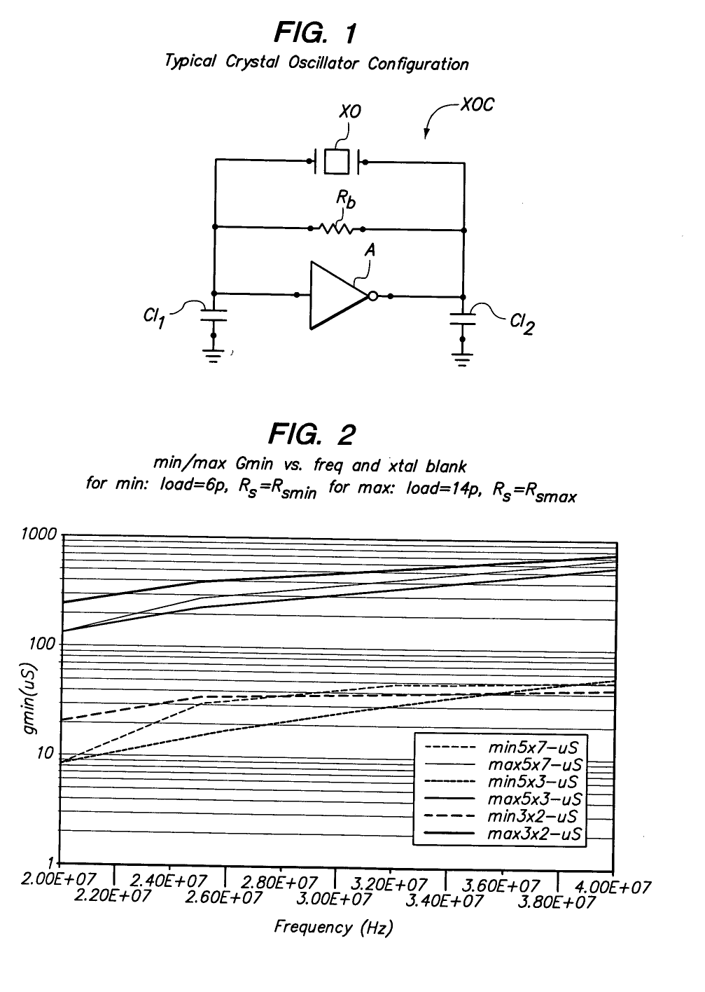

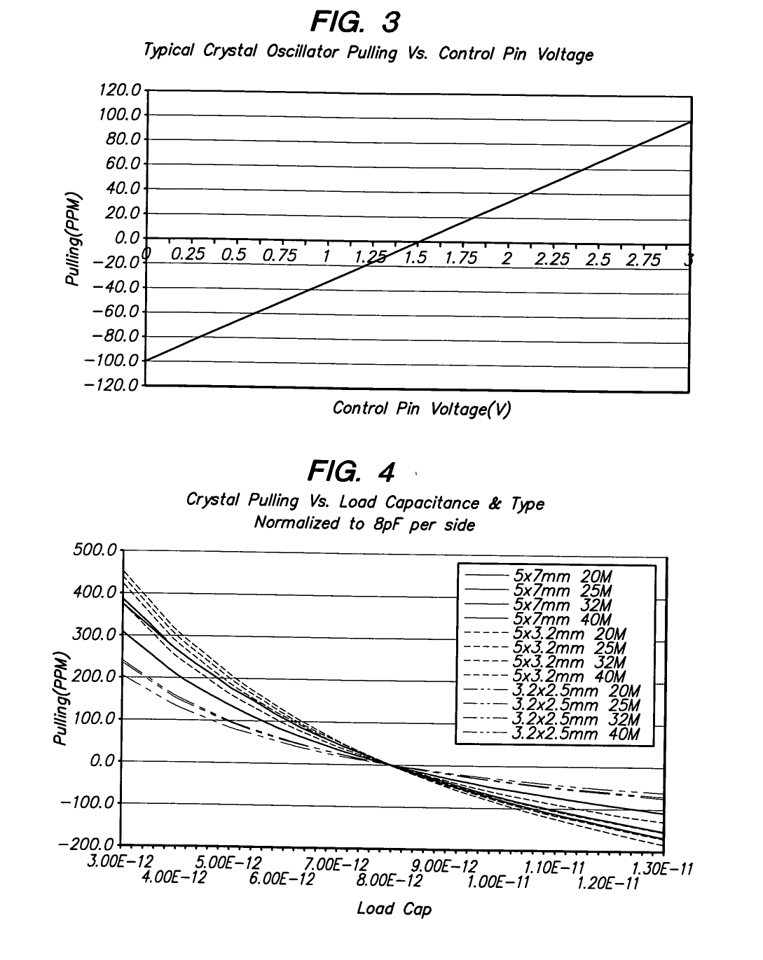

### DETAILED DESCRIPTION OF THE PREFERRED EMBODIMENTS

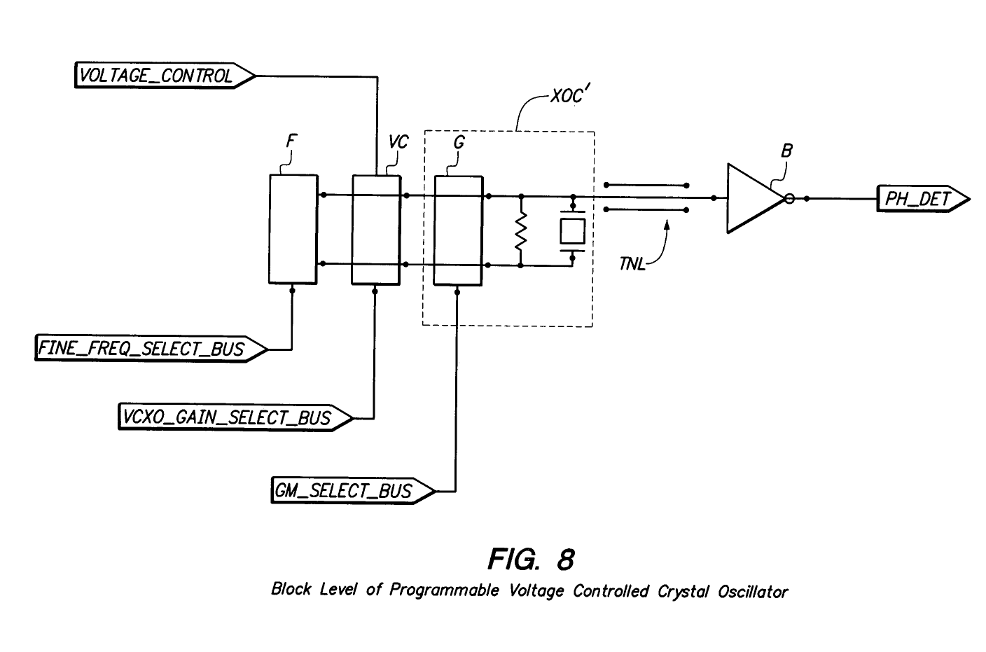

Referring now to FIG. 8, a block diagram is shown of a PXO/PVCXO in accordance with the present invention. An oscillator portion of the circuit may be configured, for example, as a Pierce oscillator and operates in cooperation with capacitive load elements located within other blocks of the circuit, to be described. The PXO/PVCXO of the illustrated embodiment comprises a programmable fine frequency adjust stage, a programmable pulling stage for realizing the VCXO function, a programmable Gm stage, a bias resistance, a “tunnel” stage TNL used to tune out parasitic interconnect capacitance, and a buffer stage used to square up the sinusoidal signal of the crystal oscillator. Each programmable stage is controlled through its respective select bus by configuration information stored in a non-volatile memory (NVM, not shown).

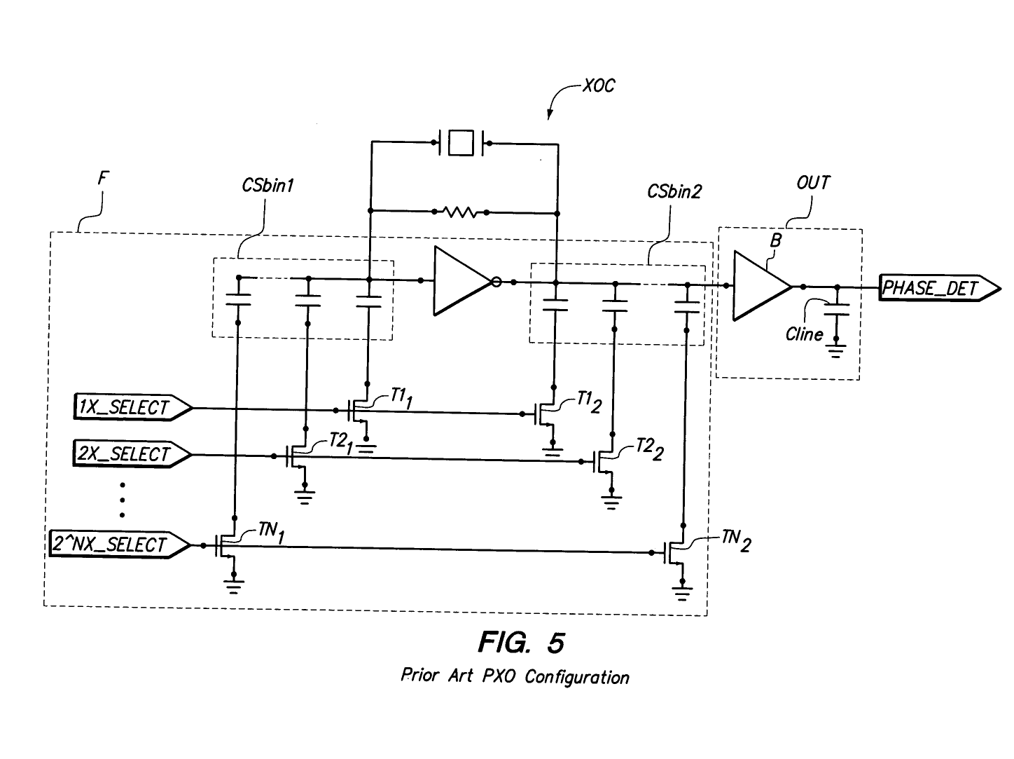

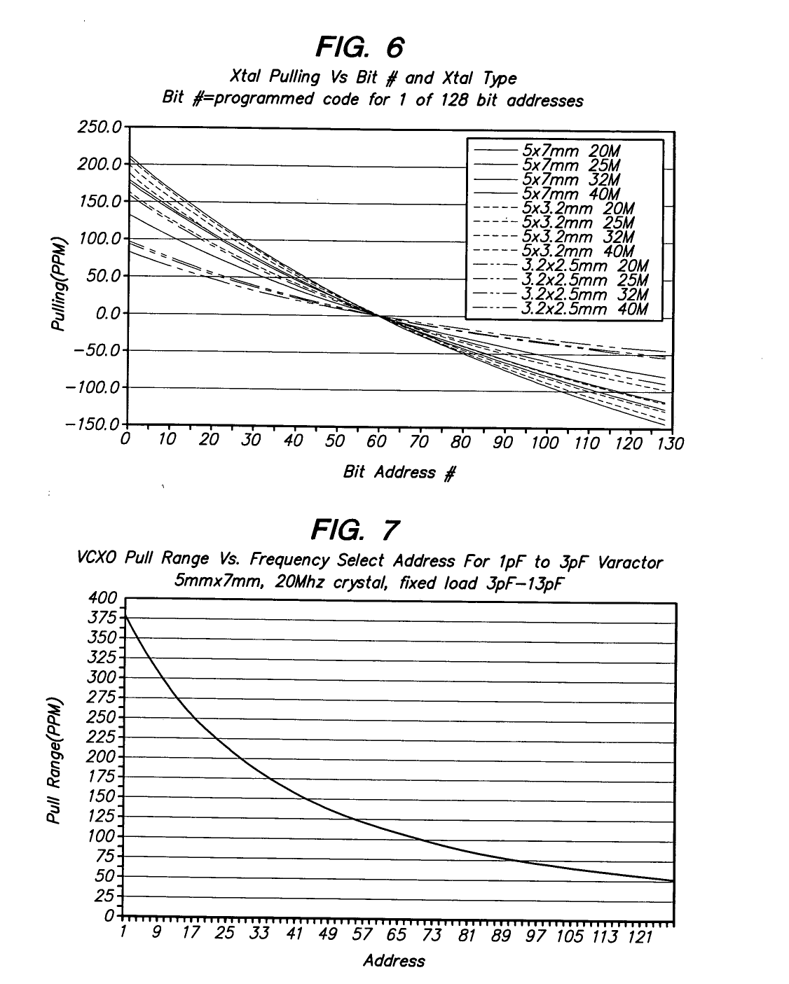

More particularly, the crystal oscillator configuration XOC′, fine frequency adjust stage F and output circuit B correspond generally to elements XOC, F and B of FIG. 5. The crystal oscillator configuration XOC′, however, now includes a variable transconductance stage, or amplifier, G. A VCXO pulling stage VC is added. The variable transconductance stage G, the fine frequency adjustment stage F, and the VCXO pulling stage VC are all connected to the pads (CRYSTAL_IN, CRYSTAL_OUT) of the crystal oscillator configuration XOC′. Also, each of the stages has an associated control bus (GM_SELECT BUS, FINE_FREQ_SELECT_BUS and VCO_GAIN_SELECT_BUS, respectively.) The VCXO pulling stage VC has a VOLTAGE_CONTROL input signal. This is an analog input signal provided via an external pin by the user. The output circuit B is connected to the crystal oscillator configuration through a tunnel stage TNL as explained in further detail below. The tunnel stage enables the output buffer to be moved close to an input terminal PH_DET of a phase detector (not shown). As a result, the capacitor representing the capacitance of the metal interconnect line (Cline in FIG. 5) is no longer shown.

The fine frequency adjust stage consists of binary weighted capacitors (capacitor pairs) that are switched into the tank through NMOS switches as illustrated in FIG. 5. Preferably, the number of binary weighted capacitors is large enough to achieve fine frequency steps over a wide frequency range. In an exemplary embodiment, the number of capacitor pairs is seven, resulting in 128 possible address words.

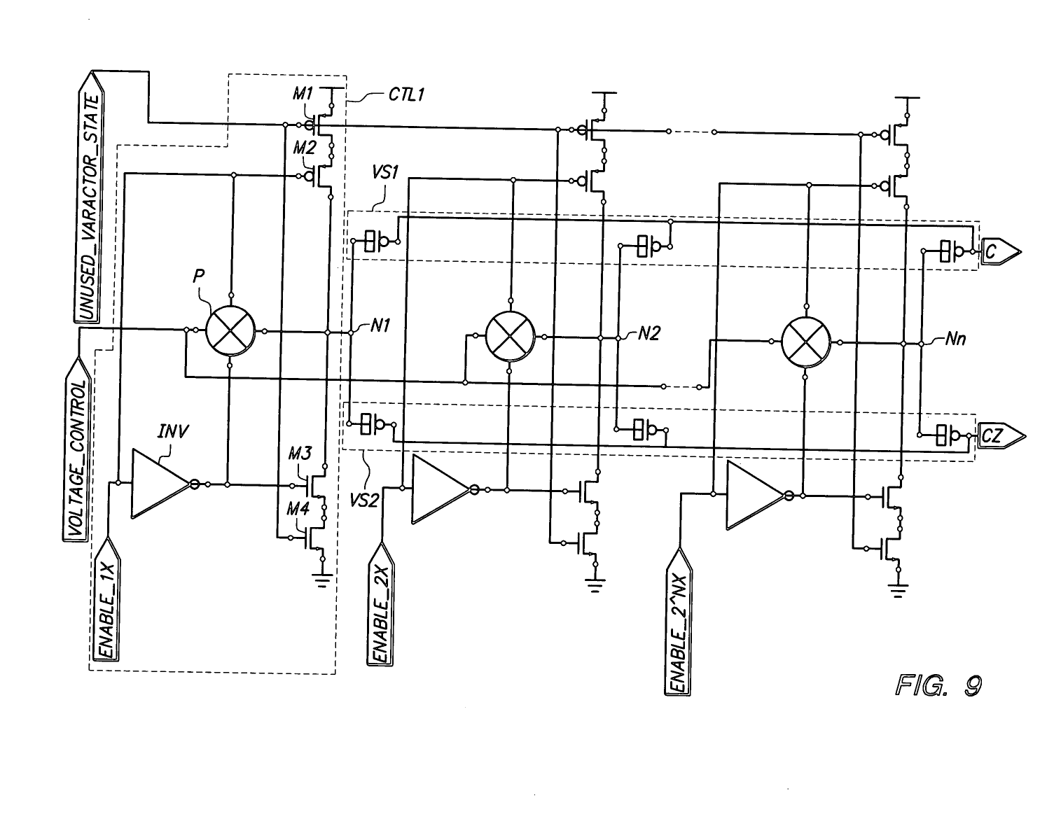

Referring to FIG. 9, the VCXO pulling stage consists of binary weighted varactors that are switched either onto the tuning line or to a minimum (cmin) or maximum (cmax) capacitance state. The cmin/cmax state of unused varactors is determined by the state of the common “UNUSED_VARACTOR_STATE” bus, which is set to ground for cmin, and to VDD for cmax. The number of cells selected is determined by the tuning gain desired for any given fine frequency adjust address. When all cells are deselected, the oscillator will act as an XO, as opposed to a VCXO.

More particularly, a series of binary weighted varactors VS1 is formed with one plate of each varactor being connected to one side (CRYSTAL_IN) of the crystal oscillator configuration. The other plate of the respective varactors is connected to respective control voltage nodes N1, N1, etc. A complementary series of binary weighted varactors VS2 is connected to the other side of the crystal oscillator configuration. Capacitors of the same weight on opposite sides of the crystal oscillator configuration are paired together, and are commonly controlled. Hence, the state of each varactor pair is determined by a voltage applied to the control voltage node. That voltage may be a supply voltage VDD, a reference voltage VSS, or an intermediate control voltage (VOLTAGE_CONTROL) applied by the user. A circuit CTL1 that determines a voltage applied to the control voltage node N1 will be described.

The control voltage node N1 is connected to VDD through a pair of PMOS transistors M1, M2, to VSS through a pair of NMOS transistors M3, M4, and to a voltage control input signal through a pass gate P. An enable signal ENABLE_1X is applied in its true form to one side of the pass gate and to the PMOS transistor M2. The enable signal is inverted by an inverter INV and is applied in its inverted form to the other side of the pass gate P and to the NMOS transistor M3. When the enable signal is asserted, the pass gate is opened, and the VOLTAGE_CONTROL signal is applied to the control voltage node N1. At the same time, the PMOS transistor M2 and the NMOS transistor M3 are rendered non-conducting.

An UNUSED_VARACTOR_STATE signal is applied to the PMOS transistor M1 and to the NMOS transistor M4. Depending on the value of this signal, one of these two transistors is rendered conducting and the other non-conducting. As a result, when the UNUSED_VARACTOR_STATE signal is low, the voltage VDD is applied to the source of the PMOS transistor M1 while the source of the NMOS transistor M4 remains floating. When the UNUSED_VARACTOR_STATE signal is high, the voltage VSS is applied to the source of the NMOS transistor M4 while the drain of the NMOS transistor M1 remains floating. When the enable signal is deasserted, the voltage determined by the UNUSED_VARACTOR_STATE signal is applied to the control voltage node.

Note that UNUSED_VARACTOR_STATE signal is connected in common to all of the varactor pairs. Similarly, the VOLTAGE_CONTROL signal is connected in common to all of the varactor pairs. Hence, if a varactor pair is enabled, it will be controlled by the VOLTAGE_CONTROL signal. If a varactor pair is not enabled, it, along with any and all other varactor pairs not enabled, will be set to either a minimum capacitance state or a maximum capacitance state depending on the UNUSED_VARACTOR_STATE signal.

The VCXO pulling stage may be programmed to achieve a desired pulling gain, independent of the chosen frequency of operation (i.e., independent of the address number of the fine frequency adjust stage). To illustrate, the amount of pulling for a crystal, in parts per million (PPM) is given by the following first order equation:

Pulling=5×10⁵*C₁/(C₀+C_{load}) (2)

where C1 and C0 are crystal parameters such as those found in table #1, and C_{load} is the total capacitance per side of the oscillator.

For the programmable case, it is convenient to decompose (1) into the components that determine the center pull value, P, and the pulling gain dP:

P+dP=5×10⁵*C₁/(C₀+C_{dig}+C_{dvar}) (3)

where:

C_{dig}=Total fixed capacitance composed of capacitance from parasitics, programmed capacitance from the fine frequency adjust stage, and the minimum capacitance from the programmed VCXO pulling stage; and

C_{dvar}=the difference of the maximum minus minimum capacitance from the programmed VCXO pulling stage. This value represents the change in pulling, and therefore pulling gain.

As seen in (3), setting C_{dvar} equal to zero, which implies no varactors are programmed, leads to no change in pulling, and therefore dP is zero. By increasingly programming varators on to the control line, dP will increase in as shown in (3). It is therefore possible to select a center frequency for the oscillator (i.e., pulling), and then adjust dp (pulling gain), in a relatively independent manner.

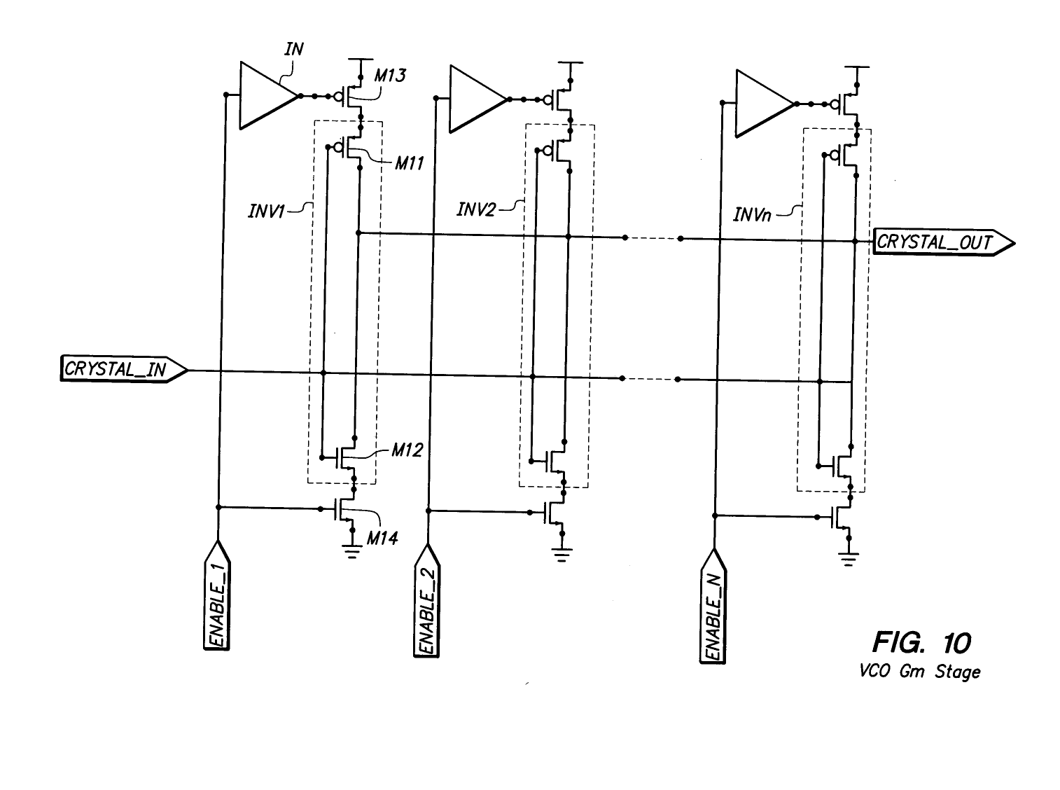

Referring to FIG. 10, the transconductance (Gm) stage G consists of N selectable CMOS inverters used to offset resistive losses found in the crystal tank. The number of individual Gm cells is determined by the various crystal and transistor parameters, and by the desired startup voltage. The inverters can be implemented as shown, or as current source loaded NMOS or PMOS inverters.

More particularly, the inverter stages INV1, INV2, etc. are connected in common with CRYSTAL_IN as the input signal and CRYSTAL_OUT as the output signal. Separate enable signals ENABLE_1, ENABLE_2, etc. are provided for each inverter and determine whether a particular inverter will be connected or will be disconnected (floating). Taking as example the first inverter INV1, the inverter itself is formed by a PMOS transistor M11 and an NMOS transistor M12 connected in series, drain to drain with the drains also being connected to the output signal CRYSTAL_OUT. The gates of the transistors are connected to the input signal CRYSTAL_IN. The voltage VDD is applied through a PMOS transistor M13 to the source of the PMOS transistor M11. A voltage VSS (ground) is applied through an NMOS transistor M14 to the source of the NMOS transistor M12. An enable signal ENABLE_1 is applied in its true form to the NMOS transistor M14. The enable signal is inverted by an inverter IN and is applied in its inverted form to the PMOS transistor M13. When the enable signal is asserted, the PMOS transistor M13 and the NMOS transistor M14 are both caused to conduct, thereby connecting the inverter INV1 to its supply voltages. When the enable signal is deasserted, both transistors are rendered non-conducting, removing the supply voltages from the inverter INV1.

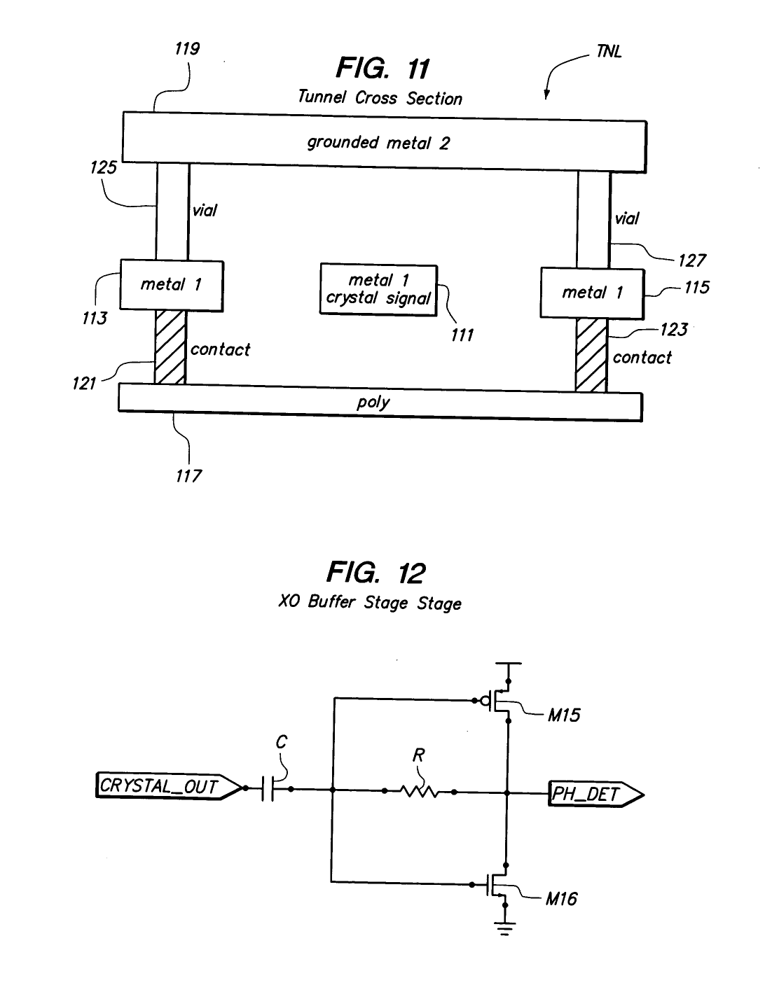

Referring to FIG. 11, a tunnel stage extends the CRYSTAL_OUT node (or, alternatively, the CRYSTAL_IN node) into the interior of the die, up to the phase detector, routed on metal one, and surrounded on all sides by grounded metal. In this configuration, the parasitic capacitance of the long metal line is tuned out by the LC tank formed by the crystal and large load capacitors, thereby removing the need to drive it with a buffer. The tunnel also shields the crystal signal from any signals resident on the die. The high drive buffer stage is then relocated from the XO to the phase detector, and is replaced with a low drive buffer which is only used to create a rail to rail square wave for the phase detector.

More particularly, if the signal plane containing the crystal signal CRYSTAL_OUT is assumed to be a Metal 1 layer, then that signal line 111 is flanked on both sides for the length of the tunnel by additional lines 113 and 115. A Metal 2 layer overlies the Metal 1 layer. A polysilicon layer underlies the Metal 1 layer. A “floor” 117 of the tunnel is formed within the polysilicon layer. A “roof” 119 of the tunnel is formed within the Metal 2 layer and is connected to ground, The “walls” of the tunnel are completed by forming multiple, minimum spaced contacts 121, 123 between the polysilicon floor feature 117 and the lines 113, 115 and by forming multiple, minimum spaced vias 125, 127 between the lines and Metal 2 roof feature 119. Dielectric material surrounds the CRYSTAL_OUT signal. The resulting structure is comparable to a length of coaxial cable at microscopic scale.

The buffer stage is shown in FIG. 12. It may comprise a simple resistor biased inverter which is ac coupled to the crystal signal node.

More particularly, the inverter is formed by a PMOS transistor M15 and an NMOS transistor M16 connected in series, drain to drain with the drains also being connected to the output signal PH_DET. The gates of the transistors are connected through a coupling capacitor C to the input signal CRYSTAL_OUT. In addition, the input signal is connected to the output signal through a bias resistor R. Since the inverter is AC coupled to the crystal circuit, it is necessary to place a DC bias on the input. The bias resistor holds the inverter at its threshold, such that small input signals cause the input to swing around that threshold, and give symmetric output signals.

As described in the foregoing description, a flexible clock circuit is provided that achieves both economy and high performance. The ability to use a variety of different crystals (without sacrificing performance) tends to minimize crystal cost. The ability to configure a single die as either a PXO or PVCXO (without sacrificing performance) reduces inventory and supply chain cost. Performance is further increased by eliminating troublesome interconnect capacitance leading up to the phase detector of an on-chip PLL.

It will be appreciated by those of ordinary skill in the art that the invention can be embodied in other specific forms without departing from the spirit or essential character thereof. The foregoing description is therefore intended in all respects to be illustrative and not restrictive. The scope of the invention is indicated by the appended claims rather than the foregoing description, and all change with come within the meaning and range of equivalents thereof are intended to be embraced therein.

What is claimed is:

1. A method of programming a programmable crystal oscillator, comprising:
determining a resistance Rs of a crystal of the programmable crystal oscillator; and
programming a transconductance of an output stage of the programmable crystal oscillator with reference to the resistance Rs.

2. A method of programming a programmable clock circuit comprising a variable load circuit coupled to an oscillator, the method comprising configuring the variable load circuit in accordance with one of a first configuration and a second configuration, where:
in a first configuration of the variable load circuit, the clock circuit produces a clock signal having a nominal center frequency and an actual frequency, the actual frequency being tuned away from the nominal center frequency using a pulling voltage input signal; and
in a second configuration of the variable load circuit, the pulling voltage input signal is disabled.

3. A method of configuring a clock circuit comprising a crystal oscillator coupled to an integrated circuit, the crystal oscillator comprising a crystal coupled to a tank circuit, the crystal having a series resistance, the method comprising:
configuring a variable output drive strength of the integrated circuit with reference to said series resistance by non-volatilely storing information on the integrated circuit; and
configuring a variable load coupled to the tank circuit by non-volatilely storing information on the integrated circuit.

4. The method of claim 3, wherein the clock circuit produces a clock signal having a nominal center frequency and an actual frequency, the actual frequency being tuned away from the nominal center frequency using a pulling voltage input signal, comprising configuring the variable load circuit with reference to the nominal center frequency.

5. The method of claim 3, comprising configuring the variable load circuit in accordance with one of a first configuration and a second configuration, where:
in a first configuration of the variable load circuit, the clock circuit produces a clock signal having a nominal center frequency and an actual frequency, the actual frequency being tuned away from the nominal center frequency using a pulling voltage input signal; and
in a second configuration of the variable load circuit, the pulling voltage input signal is disabled.

6. A clock circuit comprising:
a crystal oscillator coupled to an integrated circuit, the crystal oscillator comprising:
a crystal; and
a tank circuit coupled to the crystal;
the integrated circuit comprising:
a variable load circuit coupled to the tank circuit;
a variable output drive circuit coupled to the variable load circuit; and
non-volatile storage storing information for configuring the variable load circuit and the variable output drive strength circuit.

7. The apparatus of claim 6, wherein the crystal comprises a series resistance, the variable output drive circuit being configured with reference to a value of the series resistance.

8. The apparatus of claim 6, wherein the clock circuit produces a clock circuit having a nominal center frequency and an actual frequency, the actual frequency being tuned away from the nominal center frequency using a pulling voltage input signal.

9. The apparatus of claim 8, wherein the variable load circuit is configured with reference to the nominal center frequency.

10. The apparatus of claim 9, wherein the variable load circuit is configured such that a pulling voltage gain of the clock circuit approximates a known value.

11. The apparatus of claim 6, wherein:
in a first configuration of the variable load circuit, the clock circuit produces a clock circuit having a nominal center frequency and an actual frequency, the actual frequency being tuned away from the nominal center frequency using a pulling voltage input signal; and
in a second configuration of the variable load circuit, the pulling voltage input signal is disabled.

12. A clock circuit comprising:
an oscillator; and
an integrated circuit comprising a variable load circuit coupled to the oscillator and non-volatile storage storing information for configuring the variable load circuit;
wherein the clock circuit produces a clock circuit having a nominal center frequency and an actual frequency, the actual frequency being tuned away from the nominal center frequency using a pulling voltage input signal applied to the variable load circuit.

13. The apparatus of claim 12, wherein the variable load circuit is configured with reference to the nominal center frequency.

14. The apparatus of claim 12, wherein the variable load circuit is configured such that a pulling voltage gain of the clock circuit approximates a known value.

15. A voltage controlled oscillator comprising:
an oscillator; and
a variable load circuit coupled to the oscillator and having a plurality of unequally weighted variable load elements, wherein during operation each of the plurality of load elements is set to one of multiple different states including at least a minimum load state and a maximum load state.

16. The apparatus of claim 15, wherein said multiple different states include a variable load state in which the load element presents a load within a range between a minimum load and a maximum load in accordance with an applied control signal.

17. The apparatus of claim 16, wherein the plurality of variable load elements are divided into two groups, each variable load element in a first one of the groups being set to the variable load state, each variable load element in a second one of the groups being set to one of the minimum load state and the maximum load state.

18. A method of configuring a clock circuit comprising an oscillator and a variable load circuit coupled to the oscillator and having a plurality of unequally weighted variable load elements, the method comprising:
prior to operation, setting each of the plurality of load elements to one of multiple different states including at least a minimum load state and a maximum load state.

19. The method of claim 19, wherein said multiple different states include a variable load state in which the load element presents a load within a range between a minimum load and a maximum load in accordance with an applied control signal.

20. The method of claim 19, wherein the plurality of variable load elements are divided into two groups, each variable load element in a first one of the groups being set to the variable load state, each variable load element in a second one of the groups being set to one of the minimum load state and the maximum load state.
